(19) United States
(12) Patent Application Publication
(10) Pub. No.: US 2009/0029132 A1
(43) Pub. Date: Jan. 29, 2009

(54) COATED HARD METAL MEMBER

(75) Inventors: Jose Luis Garcia, Wien (AT); Reinhard Pitonak, Bruck/Mur (AT); Klaus Udier, Graz (AT)

Correspondence Address: GREENBLUM & BERNSTEIN, P.L.C., 1950 ROLAND CLARKE PLACE, RESTON, VA, 20191, US

(73) Assignee: BOEHLERIT GmbH & CO. KG.,, Kapfenberg (AT)

(21) Appl. No.: 12/094,043

(22) PCT Filed: Nov. 17, 2005
(86) PCT No.: PCT/AT2005/000466

§ 371 Date: Sep. 3, 2008

(51) Int. Cl. B32B 7/02; B32B 15/04; C23C 16/06

(52) U.S. Cl. 428/216; 428/336; 427/255.394; 428/472

(57) ABSTRACT

The invention relates to a coated hard metal body with increased wear resistance by means of a CVD coating and to a method for the production thereof. In order to improve the wear behavior of hard metal bodies, preferably cutting tools, in particular to reduce a crater wear, it is provided according to the invention that the sintered compact contains more than 5% by weight mixed carbides of the elements Ti and/or Nb and/or Ta, has on the surface a conditioning area with a carbon content and a nitrogen content that increases towards the outside, and has a fine-grained or microcrystalline bearing layer of nitride and/or carbide and/or carbonitride, which layer is applied according to the CVD method at a temperature exceeding 900° C.

The invention relates to a coated hard metal body with increased wear resistance, formed by sintering carbides and optionally carbonitrides as well as binding metal with a CVD coating applied to the sintered compact.

Furthermore, the invention relates to a method for producing a coated hard metal body.

Hard metal bodies are composite materials and essentially comprise one type or in particular several types of hard material powders that are joined by means of a binding metal. Carbides, nitrides or carbonitrides of elements of groups 4, 5 and 6 of the periodic system are used as hard material, wherein cobalt, nickel and/or iron and alloys of these metals with concentrations of 2 to 30% by weight are used as binding metal in the body. At best the main constituent of hard metal is tungsten carbide.

Compared to annealed steels and metallic alloys, hard metal bodies have a much greater hardness and are often used as cutting elements such as cutting inserts. In order to further increase the edge-holding ability of the cutting elements and to reduce wear, a hard material coating of the surface of the hard metal body is carried out throughout.

Coatings on hard metal bodies should be very hard and have a high adhesive strength on the substrate in order to render possible long service lives or high cutting capacities with mechanical and thermal loads, for example, during use as a tool for chip removal.

A high hardness of the coating and the hard metal bodies, however, can promote the crack initiation, in particular with intermittent load and can cause chips or separation fractures.

To solve the problem of crack initiation and crack propagation in coated hard metal parts, it was proposed and is prior art to effect an increase of the binding metal in the zone close to the surface during sintering and/or through a heat treatment in vacuum and in this manner to set a higher material toughness, albeit with reduced material hardness, in this region.

A coating with increased thickness thereby acts as a very hard, wear-resistant means and the softer and tougher zone lying beneath acts as a means of preventing crack propagation, followed by the again harder and more brittle hard metal body.

In order to increase the wear resistance of the surface of the hard metal body it was also proposed (DE-OS-27 17 842) to increase the nitrogen content thereof so that a nitrogen content that decreases towards the inside of a surface layer is present. The hard metal object therefore does not thereby bear a coating, instead the wear resistance and hardness of the material are embodied to increase towards the outside.

It is to be considered a great disadvantage of this surface layer enriched with nitrogen of the hard metal body that no coating that has a high adhesive strength on the substrate can be applied thereto.

The object of the invention here is to eliminate the disadvantages of the prior art and to create a coated hard metal body of the type mentioned at the outset that does not exhibit any tough surface area impeding crack propagation with a reduction in hardness, but instead has a uniform hardness of the outer area, in particular a hardness increasing towards a coating. The object of the invention is also to condition the surface of the hard metal body such that a very hard coating provides a high resistance to a detachment of the same. The object according to the invention also comprises an increase in the wear resistance of the coated hard metal object with reduced crack initiation, in particular a reduction of the crater wear with cutting tools.

Furthermore, the object of the invention is to disclose a method for producing a coated hard metal body that exhibits the aforementioned objectives.

These objects are attained with a generic hard metal body in which the sintered compact contains more than 5% by weight of carbide(s) or carbonitride(s) of at least one of the elements Ti and/or Nb and/or Ta, has on the surface a conditioning area with a carbon content and a nitrogen content that increases towards the outside, and has a fine-grained or microcrystalline bearing layer of nitride and/or carbide and/or carbonitride, which bearing layer is applied according to the CVD method at a temperature exceeding 900° C.

The advantages attained with the invention are to be seen essentially in that through the composition of the sintered compact a prerequisite is created for a production of a conditioning area on the surface thereof. This conditioning area has a uniform or steadily increasing hardness from the hard metal interior towards the outside and a carbon content and an increased nitrogen concentration, which are a basis for a high adhesive force or bond of a coating. It is important for a coating that it is applied by means of the high-temperature CVD method, because particularly good adhesion criteria can be achieved due to the reaction kinetics given at these temperatures. The carbon of the conditioning region is incorporated into the coating during the application thereof, which leads to a particularly deep connection between area and coating. In other words: the carbon is virtually suctioned into the forming coating from the substrate surface at a temperature of 900° C. and above and through diffusion imparts with nitrogen a continuous transition with excellent adhesion of the coating. Brittle phases or C pores in the border region are thereby completely avoided.

It is advantageous if the sintered compact contains more than 7.5% by weight, preferably more than 8.5% by weight, in particular more than 10% by weight, of carbides or carbonitrides of the elements Ti and/or Nb and/or Ta. Low contents of so-called mixed carbides impair the formation of the conditioning area so that its lower limit is 7.5% by weight. The best embodiments of the conditioning area are given in a concentration range of 10 to 40% by weight of mixed carbides.

The sintered compact can per se have increased binding metal contents and thus improved toughness properties because the material hardness of the coated hard metal object now usually increases towards the surface. To avoid brittle fractures and edge fractures, however, it is advisable for a sintered compact according to the invention to have a binding metal content in % by weight of more than 6%, preferably more than 8%, in particular approx. 10% and higher.

With respect to a desired embodiment of the conditioning area and a good adhesion prerequisite on the surface thereof, it is favorable if the binding metal is made of cobalt or an alloy of cobalt and/or nickel with iron, wherein the iron content is preferably 5 to 80% by weight, in particular up to 50% by weight. The iron in the binding metal has a catalytic function for an enrichment of carbonitride of the elements Ti, Nb, Ta on the surface of the conditioning area and thus to create particularly good prerequisites for an adhesion of a coating thereon. Iron contents below 5% by weight no longer show a desired result, in contrast, over 80% by weight of iron in the binding metal acts too intensively on the progress of a carbonitride formation.

If, as can be furthermore provided according to the invention, the binding metal is made from a secondarily age-hardenable alloy, in particular an alloy with a composition similar to that of high-speed steels, a further increase in hardness of the hard metal object can be achieved.

As mentioned above, it is of particular advantage if material hardness of at least the same level is present from the inner sintered compact to the surface in the conditioning area, preferably increasing hardness, in particular evenly increasing hardness of the material is given, wherein the hardness is determined as an average value with the Vickers microhardness test (HV_{0.1}). In this manner a coating constructed from one or more layers can be embodied in a thin and elastic manner and can combat a crack initiation.

It is advantageous for a stability and an ensured quality of the entire surface zone of a hard metal body according to the invention if the conditioning area has a thickness of at least 3 μm, preferably of at least 5 μm to 50 μm. In the conditioning area low contents of tungsten carbide, e.g., of 20 to 35% by weight, and low binding metal contents of 3.5 to 5.5% by weight are advantageously present at the surface, so that with a thickness of the conditioning area of less than 3 μm a sudden change in structure is given, which increases the danger of a crack initiation. Conditioning area depths greater than 50 μm can be produced with increased expenditure and do not provide any further improvements in the adhesion of the coating.

An adhesive strength of the coating with an area keying in the nanometer range and an initiation of a microcrystalline embodiment of the coating can be achieved if the conditioning area has a content of 40 to 80% by weight carbonitride of metals of the groups 4 and 5 of the periodic system, preferably such a content of 50 to 70% by weight, and tungsten carbide (WC) and binding metals.

It is provided with a particularly advantageous embodiment of the invention that the coating or the bearing layer applied to the conditioning area of the sintered compact according to the high-temperature method is embodied in a microcrystalline and structured manner and when examined under the microscope has a reddish orange color with darker stripes and comprises essentially titanium carbonitride (Ti(CₓN_{y})). In this manner on the one hand an optimal adhesion of the coating on the conditioning area of the hard metal body can be achieved, on the other hand the structure of the bearing layer significantly reduces the crack initiation and the crack propagation therein.

The surface area of the conditioning layer has a higher content of mixed carbide so that a coating of titanium carbonitride is continuously formed further and has the best adhesion.

If the titanium-carbonitride coating bears a cover layer formed essentially of aluminum oxide (Al₂O₃), as can be advantageously provided, the cutting capacity of the tool is substantially increased and the crater wear is reduced. The Al₂O₃ cover layer acts as a reaction or oxidation protection as well as a thermal protection of the poor thermal conduction due to the oxide layer for the titanium carbonitride coating lying beneath.

It can also be favorable for increasing the service life of a tool if the titanium carbonitride coating bears a layer formed essentially of titanium aluminum nitride ((TiₓAl_{y})N).

In a particular form of the invention with optimized wearing qualities for indexable cutting inserts in hard operation it is advantageous if the conditioning area on the sintered compact has a thickness of 1 to 35 μm, preferably 2 to 25 μm, the Ti(CₓN_{y}) coating or bearing layer has a thickness of 1 to 22 μm, preferably 2 to 15 μm, and optionally an Al₂O₃ cover layer with a thickness of 1 to 25 μm, preferably 1 to 15 μm or a (TiₓAl_{y})N cover layer with a thickness of 0.5 to 12 μm, preferably 0.6 to 0.9 μm.

The other object of the invention is achieved with a generic method in that a sintered compact or hard metal body with more than 5% by weight mixed carbides of the elements Ti and/or Nb and/or Ta with desired geometric dimensions is formed from a pressed blank or greenbody by means of sintering, wherein or whereupon on the surface a conditioning area with a carbon content and a nitrogen concentration increasing towards the outside is created through an annealing in an atmosphere containing nitrogen, on which conditioning area a deposition of a fine-grained or microcrystalline, structured bearing layer of carbonitride takes place according to the CVD method using (CH₄ and N₂) at a temperature of over 900° C.

The advantages of the method according to the invention are based on the composition of the greenbody and consequently of the sintered compact. With a long sintering, in particular in a vacuum, an enrichment of tungsten carbide and binding metal on the surface of the sintered compact can occur for reaction kinetic reasons. However, if a short sintering in vacuum and consequently a further sintering or an annealing under an atmosphere containing and/or emitting nitrogen is carried out, an enrichment of carbonitrides directly occurs in an area under the surface and in this manner an embodiment of a conditioning area with up to 70% titanium and/or niobium and/or tantalum carbonitrides. It is thereby essential according to the invention that carbon and nitrogen are contained in sufficient quantity in the conditioning area or in particular nitrogen is adjusted to increase towards the outside. This conditioning layer can be embodied in its dimension and composition through the parameters temperature and type of gas atmosphere emitting nitrogen, and a reduced local binding metal content, optionally being 4% by weight, and optionally a tungsten concentration reduced to 20% by weight can thereby be achieved, wherein these values do not have to represent a lower limit. With this enrichment of so-called mixed carbides on the outer surface of the conditioning area a surface structured in the nano range and a favorable prerequisite for a growth of a coating are created. A production of the coating takes place according to the CVD method, wherein a gas containing CH₄ and N₂ is used in order to provide carbon as well as nitrogen in the process. A temperature in the range above 900° C. should be used for a desired initiation of a reaction of the coating elements, wherein higher coating temperatures up to 1050° C. bring advantages. The control of the reaction is carried out such that carbon is as it were suctioned out of the surface of the conditioning layer and is inserted into the coating compound during the steam condensation so that a deep adhesion occurs between nano-structured substrate and coating.

According to the invention it is provided that a sintered compact with respectively more than 7.5% by weight, preferably more than 8.5% by weight, in particular more than 10% by weight, of mixed carbides of the elements of the group 4 and/or the group 5 of the periodic system, preferably of Ti and/or Nb and/or Ta is produced in order to create favorable prerequisites for a production of a conditioning layer formed as desired.

In the development work, it proved favorable for the product quality if a sintered compact is produced with a binding metal content of more than 6% by weight, preferably higher than 8% by weight, in particular of approx. 10% by weight and higher, and if cobalt and/or nickel and/or iron are used as a binding metal.

In a particular embodiment of the invention it can be provided by way of a simplification that powdery, metallic individual components, e.g., cobalt, nickel, iron and/or alloys thereof are added to the powdery carbides and an embodiment of the composition of the binding metal is carried out during sintering through diffusion. In this manner desired binding metal compositions can be achieved in a very economic and precise manner.

For the forming according to the invention of the surface layer bearing the coating it is important that a conditioning area with material hardness of at least the same level from the sintered compact towards the surface, preferably of increasing hardness, in particular of evenly increasing hardness (average value of a microhardness (HV_{0.1}) determination) is (are) formed and/or the binding metal content is reduced to a value of (0.25 to 0.8) times the binding metal value of the sintered compact by means of annealing on the sintered compact or hard metal body at a pressure of (1 to 20)×10⁵ Pa, preferably at a pressure of (5 to 10)×1 Pa and a temperature of less than that of the sintering temperature, but higher than 800° C. in an atmosphere containing nitrogen.

The pressure, the temperature impingement and the time are essential for an enrichment of the mixed carbides in the conditioning area. An economic treatment of the sintered compact occurs at a pressure of the atmosphere containing nitrogen of at least 1×10⁵ Pa and a temperature of more than 800° C., because an efficient reaction and diffusion of the compound elements is thereby set for the first time. A higher pressure than 20×10⁵ Pa and/or an annealing temperature of over 1050° C., in particular of over 1120° C., lead to a coarsening and a poor controllability of the embodiment of the conditioning area.

If, as according to the invention, a content of carbonitride of the groups 4 and 5 of the periodic system, preferably a content of titanium and/or niobium and/or tantalum carbonitride (Ti,Nb,Ta)(C,N) of 40 to 80% by weight, preferably 50 to 70% by weight, is adjusted in the conditioning area, it was found that an embodiment of a nanostructured surface occurs thereby on which consequently a growth of titanium carbonitride occurs in a keyed manner essentially without producing limit stresses, which growth is applied according to the high-temperature CVD method.

The best metal cutting results during turning with interrupted cutting can be achieved if a conditioning area is created with a thickness of greater than 3 μm and a microcrystalline, structured coating of essentially titanium carbonitride Ti(CₓN_{y}) with a layer thickness of 1 to 22 μm is applied thereon according to the high-temperature CVD method, on which coating a deposition of a cover layer optionally of essentially aluminum oxide (Al₂O₃) with a layer thickness of 1 to 25 μm or of essentially titanium aluminum nitride ((TiₓAl_{y})N) with a layer thickness of 0.5 to 12 μm, preferably 0.6 to 9.0 μm, takes place.

A thickness of the conditioning area lower than 3 μm can lead to a low adhesion of the coating due to an excessively high content of binder phase and tungsten carbide. The coating formed of titanium carbonitride is effective only with a thickness of 1 μm and greater, wherein the best results are achieved from approx. 6 to 9 μm. It is thereby essential for the invention to use the high-temperature CVD method, because the reaction kinetics proceed in the desired manner at temperatures above 900° C. Optionally a carbon phase can form on the substrate surface below 900° C. with the use of CH₃CN+TiCl₄ as coating gas in the presence of carbon, which carbon phase is soft and has the effect of impairing adhesion. Furthermore a coating with a grain size of optionally approx. 75 nm is formed, which usually has a gray color.

According to the invention, however, the application of the coating takes place at over 900° C., wherein it has a reddish/yellow/orange color and an average grain diameter of optionally approx. 25 nm, thus clearly forms advantageously with a finer grain size, wherein internal structures, which appear somewhat darker under the microscope, further reduce a crack initiation and substantially improve a wear resistance.

The invention is explained in more detail below based on schematic sketches and results.

They show:

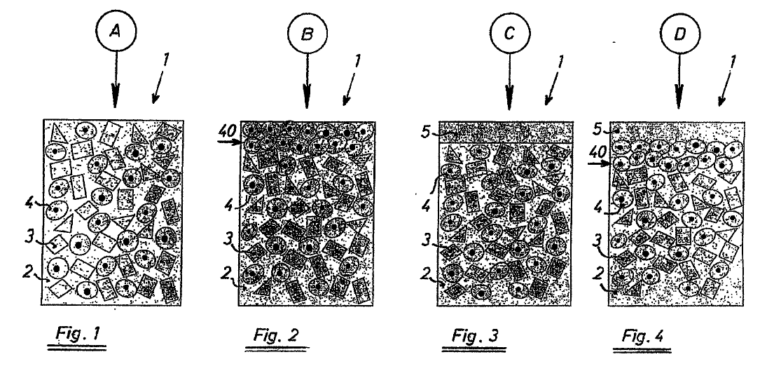

FIG. 1 Hard metal

FIG. 2 Hard metal with a conditioning area

FIG. 3 Hard metal with an HT-CVD coating

FIG. 4 Hard metal with a conditioning area and an HT-CVD coating

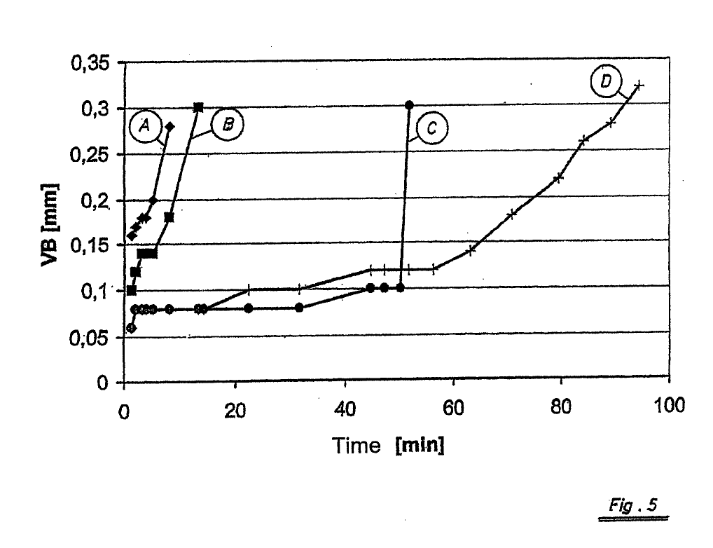

FIG. 5 Results of chip removal tests

FIG. 1 shows diagrammatically a hard metal object 1 with a designation A, which is made of a binding metal 2, in which tungsten carbide particles 3 and mixed carbide particles 4.

FIG. 2 shows a hard metal object 1 that is structured in the same manner as that in FIG. 1. However, this object has on one surface a conditioning area 40 that has higher contents of mixed carbides 4 with nitrogen contents increasing towards the outside (designation B).

FIG. 3 shows a hard metal object 1 as in FIG. 1, but this hard metal object bears an HT-CVD coating 5 and is labeled C.

FIG. 4 shows a hard metal object 1 (designation D) that has a conditioning area 40 and an HT-CVD coating 5.

FIG. 5 shows the results of chip removal tests:

Hard metal indexable inserts with the same composition, namely;

| | |
|---|---|
| Tungsten carbide (WC) | 60% by weight |
| Mixed carbide (Ti, Nb, Ta)C | 30% by weight |
| Binding metal (Co) | 10% by weight |

and the same geometry were produced in four different types a surface embodiment according to the designation A,B,C,D in the images 1 through 4.

Cuts were respectively carried out on a lathe tool with a composition according to DIN material number 1.6582 at a cutting speed of 220 m/min a cutting depth of 2 mm and a feed of 0.28 mm per revolution with dry cutting, wherein the wear area was measured at time intervals.

It can be seen from the representation that a service life improvement has been achieved compared to hard metal A with a conditioning area (curve B) through its high hardness.

An effect of a high-temperature CVD coating improving the service life on hard metal (curve C) and on hard metal with a conditioning area (curve D) can be clearly seen.

With a tool according to the invention (curve D) it was furthermore established that a wear rate is embodied in a manner rising only slowly because a particularly marked adhesion of the coating to a substrate with a high conditioning area with high hardness, in particular with high abrasion resistance, is present.

1. Coated hard metal body with increased wear resistance, formed by sintering carbides and optionally carbonitrides as well as binding metal with a CVD coating applied to the sintered compact, wherein the sintered compact contains more than 5% by weight of mixed carbides of the elements Ti and/or Nb and/or Ta, has on the surface a conditioning area with a carbon content and a nitrogen content that increases towards the outside, and has a fine-grained or microcrystalline bearing layer of nitride and/or carbide and/or carbonitride, which bearing layer is applied according to the CVD method at a temperature exceeding 900° C.

2. Hard metal body according to claim 1, characterized in that the sintered compact contains more than 7.5% by weight, preferably more than 8.5% by weight, in particular more than 10% by weight, of carbide or carbonitride of the elements Ti and/or Nb and/or Ta.

3. Hard metal body according to claim 1, characterized in that the sintered compact has a binding metal content in % by weight of more than 6%, preferably more than 8%, in particular approx. 10% and higher.

4. Hard metal body according to claim 3, characterized in that the binding metal is made of cobalt or an alloy of cobalt and/or nickel with iron, wherein the iron content is preferably 5 to 80% by weight, in particular up to 50% by weight.

5. Hard metal body according to claim 3, characterized in that the binding metal is made from a secondarily age-hardenable alloy, in particular an alloy with a composition similar to that of high-speed steels.

6. Hard metal body according to claim 1, characterized in that a material hardness of at least the same level is present from the inner sintered compact to the surface in the conditioning area, preferably increasing hardness, in particular evenly increasing hardness of the material is given, wherein the hardness is determined as an average value with the Vickers microhardness test (HV_{0.1}).

7. Hard metal body according to claim 1, characterized in that the conditioning area has a thickness of at least 3 μm, preferably of 5 μm to 50 μm.

8. Hard metal body according to claim 1, characterized in that the conditioning area has a content of 40 to 80% by weight carbonitride of metals of the groups 4 and 5 of the periodic system, preferably such a content of 50 to 70% by weight, and tungsten carbide (WC) and binding metals.

9. Hard metal body according to claim 1, characterized in that the coating or the bearing layer applied to the conditioning area of the sintered compact according to the high-temperature method is embodied in a microcrystalline and structured manner and when examined under the microscope has a reddish orange color with darker stripes and comprises essentially titanium carbonitride (Ti(CₓN_{y})).

10. Hard metal body according to one of the claim 1, characterized in that the titanium-carbonitride coating bears a cover layer comprising essentially aluminum oxide (Al₂O₃).

11. Hard metal body according to claim 1, characterized in that the titanium-carbonitride coating bears a layer comprising essentially titanium aluminum nitride (TiₓAl_{y})N).

12. Hard metal body according to claim 1, characterized in that the conditioning area on the sintered compact has a thickness of 1 to 35 μm, preferably 2 to 25 μm, the Ti(CₓN_{y}) coating or bearing layer has a thickness of 1 to 22 μm, preferably 2 to 15 μm, and optionally an Al₂O₃ cover layer with a thickness of 1 to 25 μm, preferably 1 to 15 μm, or a (TiₓAl_{y})N cover layer with a thickness of 0.5 to 12 μm, preferably 0.6 to 0.9 μm.

13. Method for producing coated hard metal bodies by sintering carbides and binding metals with the application of a CVD coating on the sintered compacts, wherein a sintered compact or hard metal body with more than 5% by weight mixed carbides of the elements Ti and/or Nb and/or Ta with desired geometric dimensions is formed from a pressed blank or greenbody by means of sintering, wherein or whereupon on the surface a conditioning area with a carbon content and a nitrogen concentration increasing towards the outside is created through an annealing in an atmosphere containing nitrogen, on which conditioning area a deposition of a fine-grained or microcrystalline, structured bearing layer of carbonitride takes place according to the CVD method using (CH₄ and N₂) at a temperature of over 900° C.

14. Method according to claim 13, characterized in that a sintered compact is produced with respectively more than 7.5% by weight, preferably more than 8.5% by weight, in particular more than 10% by weight, of mixed carbides of the elements of the group 4 and/or the group 5 of the periodic system, preferably of Ti and/or Nb and/or Ta.

15. Method according to claim 13, characterized in that a sintered compact is produced with a binding metal content of higher than 6% by weight, preferably of higher than 8% by weight, in particular of approx. 10% by weight and higher.

16. Method according to claim 15, characterized in that cobalt and/or nickel and/or iron are used as a binding metal.

17. Method according to claim 13, characterized in that powdery, metallic individual components, for example cobalt, nickel, iron and/or alloys thereof are added to the carbides and an embodiment of the composition of the binding metal is carried out during sintering through diffusion.

18. Method according to claim 13, characterized in that a conditioning area with material hardness of at least the same level from the sintered compact towards the surface, preferably of increasing hardness, n particular of evenly increasing hardness (average value of a microhardness (HV_{0.1}) determination) is (are) formed on the surface and/or the binding metal content is reduced to a value of (0.25 to 0.6) times the binding metal value of the sintered compact by means of annealing on the sintered compact or hard metal body at a pressure of (1 to 20)×10⁵ Pa, preferably at a pressure of (5 to 10)×10⁵ Pa and a temperature of less than the sintering temperature, but higher than 800° C. in an atmosphere containing nitrogen.

19. Method according to claim 13, characterized in that in the conditioning area a content of carbonitride of the groups 4 and 5 of the periodic system, preferably a content of titanium and/or niobium and/or tantalum carbonitride (Ti,Nb,Ta)(C,N) of 40 to 80% by weight, preferably 50 to 70% by weight is adjusted.

20. Method according to claim 13, characterized in that a conditioning area is created with a thickness of greater than 3 μm and a microcrystalline, structured coating of essentially titanium carbonitride Ti(CₓN_{y}) with a layer thickness of 1 to 22 μm is applied thereon according to the high-temperature CVD method, on which coating a deposition of a cover layer optionally of essentially aluminum oxide (Al₂O₃) with a layer thickness of 1 to 25 μm or of essentially titanium aluminum nitride ((TiₓAl_{y})N) with a layer thickness of 0.5 to 12 μm, preferably 0.6 to 9.0 μm, takes place.
